(19) United States
(12) Patent Application Publication
(10) Pub. No.: US 2020/0350328 A1
(43) Pub. Date: Nov. 5, 2020

(54) SINGLE-GATE MULTIPLE-TIME PROGRAMMING NON-VOLATILE MEMORY AND OPERATION METHOD THEREOF

(71) Applicant: YIELD MICROELECTRONICS CORP., Chu-Pei City (TW)

(72) Inventors: HSIN-CHANG LIN, CHU-PEI CITY (TW); WEI-TUNG LO, CHU-PEI CITY (TW); WEN-CHIEN HUANG, CHU-PEI CITY (TW)

(21) Appl. No.: 16/401,429

(22) Filed: May 2, 2019

(51) Int. Cl. H01L 27/11558; H01L 29/08; G11C 16/04; G11C 16/10; G11C 16/14

(52) U.S. Cl. CPC H01L 27/11558; H01L 29/0847; G11C 16/14; G11C 16/10; G11C 16/0416

(57) ABSTRACT

A single-gate non-volatile memory and an operation method thereof are disclosed, wherein the non-volatile memory has a single floating gate. The non-volatile memory disposes a transistor and a capacitor structure in a semiconductor substrate. The transistor has two ion-doped regions disposed at two sides of a conduction gate to function as a source and a drain and disposed in the semiconductor substrate. The widths of the source and the drain are differently, and the edge of the drain is utilized to serve as a capacitor to control the floating gate. The minimum control voltages and elements during writing are involved to greatly reduce the area, control lines and the cost thereof.

### BACKGROUND OF THE INVENTION

### Field of the Invention

The present invention relates to a single-gate multiple-time programming non-volatile memory, particularly to a single-gate multiple-time programming non-volatile memory and an operation method thereof, wherein the edge of the drain is used as a capacitor to control the floating gate.

### Description of the Related Art

The CMOS (Complementary Metal Oxide Semiconductor) process has been a normal fabrication method for ASIC (Application Specific Integrated Circuit). EEPROM (Electrically Erasable Programmable Read Only Memory), which features electric programmability and erasability and would not lose its memory after power is turned off, has been one of the popular non-volatile memories in the computer and information age.

A non-volatile memory is programmed via keeping charges to vary the gate voltage of the transistor thereof, or not keeping charges to preserve the gate voltage of the transistor. For a non-volatile memory, an erasion operation is to eliminate all the charges kept in the non-volatile memory and restore all the transistors to have the original gate voltages. In the conventional single-gate non-volatile memory, there are many kinds of control voltages and many memory elements. Therefore, the conventional non-volatile memory has larger area and higher fabrication cost.

To overcome the abovementioned problems, the present invention provides a single-gate multiple-time programming non-volatile memory and an operation method thereof, so as to greatly reduce the area of the single-gate non-volatile memory and improve the production value of the single-gate non-volatile memory.

### SUMMARY OF THE INVENTION

A primary objective of the present invention is to provide a single-gate multiple-time programming non-volatile memory and an operation method thereof, wherein the source and the drain in the non-volatile memory have different widths. The edge of the drain can be served as a capacitor to control the floating gate. Thereby, the minimum control voltages and elements during writing are involved to reduce the whole area. Compared with a conventional single-gate programming non-volatile memory having high cost due to complicated control, the present invention can greatly reduce the control lines and cost of the non-volatile memory on account of simple operation and the least elements.

To achieve the abovementioned objectives, the present invention provides a single-gate multiple-time programming non-volatile memory, which comprises a P-type semiconductor substrate, a transistor and a capacitor structure, wherein the transistor and the capacitor structure are disposed in the P-type semiconductor substrate. The transistor comprises a first dielectric layer, a first conduction gate and two highly-conductive ion-doped regions, the first dielectric layer is disposed on the P-type semiconductor substrate, and the first conduction gate is stacked on the first dielectric layer, and the ion-doped regions are respectively disposed at two sides of the first conduction gate and the first dielectric layer to function as a source and a drain and disposed in the P-type semiconductor substrate, wherein the source and the drain have different widths. The edge of the drain is utilized to serve as a capacitor to form the capacitor structure and control a floating gate. A lightly-doped region is located between the drain and the floating gate, and the lightly-doped region and the ion-doped regions are doped with the same type of ions, jointly functioning as a single floating gate of the non-volatile memory.

In the present invention, the semiconductor substrate is a P-type semiconductor substrate or a semiconductor substrate having a P-type well, the transistor structure is an N-type transistor, and the ion-doped regions and the lightly-doped region are N-type ion-doped regions.

Besides, an operation method of the single-gate multiple-time programming non-volatile memory respectively applies a substrate voltage V_{sub}, a source voltage Vₛ and a drain voltage V_{d} to the P-type semiconductor substrate, the source and the drain, so as to perform a writing process or an erasing process.

In writing,
a. V_{sub}=ground (0);
b. V_{d}=Vₛ=HV (High Voltage);
   V_{d}=HV (High Voltage), and Vₛ=MV (Medium Voltage) or LV (Low Voltage); or
   V_{d}=MV (Medium Voltage), and Vₛ=LV (Low Voltage) or ground (0).

In erasing,
a. V_{sub}=ground (0);
b. V_{d}=HV (High Voltage), and Vₛ=floating voltage;
   V_{d}=HV (High Voltage), and Vₛ=ground (0);
   Vₛ=HV (High Voltage), and V_{d}=ground (0); or
   Vₛ=HV (High Voltage), and V_{d}=floating voltage.

Below, the embodiments are described in detail in cooperation with the drawings to make easily understood the technical contents, characteristics and accomplishments of the present invention.

### BRIEF DESCRIPTION OF THE DRAWINGS

FIG. 1 is a sectional view schematically showing the structure of a single-gate multiple-time programming non-volatile memory according to an embodiment of the present invention;

FIG. 2 is a diagram schematically showing a first layout structure of the source and the drain with different widths according to the embodiment of the present invention;

FIG. 3 is a diagram schematically showing a second layout structure of the source and the drain with different widths according to the embodiment of the present invention; and

FIG. 4 is a diagram schematically showing the single-gate multiple-time programming non-volatile memory having three terminals according to the embodiment of the present invention.

### DETAILED DESCRIPTION OF THE INVENTION

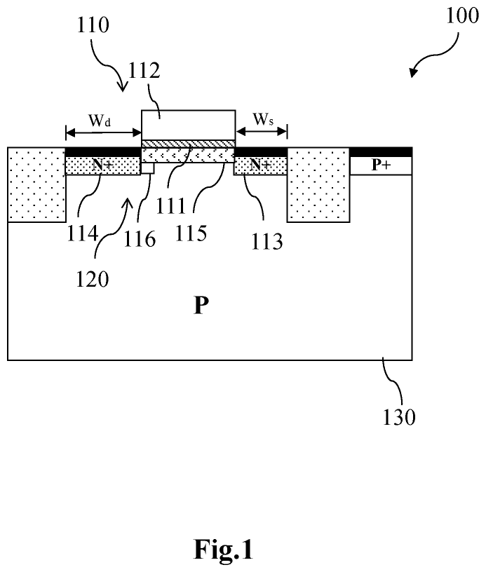

Refer to FIG. 1. FIG. 1 is a sectional view schematically showing the structure of a single-gate multiple-time programming non-volatile memory according to an embodiment of the present invention.

The single-gate multiple-time programming non-volatile memory 100 comprises a P-type semiconductor substrate 130 or a semiconductor substrate with a P-type well. In FIG. 1, the P-type semiconductor substrate 130 is used as an exemplification. An NMOS transistor (NMOSFET) 110 and an N-type capacitor structure 120 are disposed in the P-type semiconductor substrate 130. The NMOS transistor 110 comprises a first dielectric layer 111 disposed on the P-type semiconductor substrate 130; a first conduction gate 112 stacked on the first dielectric layer 111; and two ion-doped regions disposed in the P-type semiconductor substrate 130 to respectively function as a source 113 and a drain 114, wherein a channel 115 is formed between the source 113 and the drain 114. The source 113 and the drain 114 have different widths. The N-type capacitor structure 120 uses the edge of the drain 114 to serve as a capacitor and control a floating gate, jointly functioning as a single floating gate of the non-volatile memory 100. Specifically, the edge of the drain 114 is in the middle of the floating gate. Wherein, the N-type capacitor structure 120 has a lightly-doped region 116 between the drain 114 and the floating gate, and the ion-doped regions and the lightly-doped region 116 are N-type ion-doped regions.

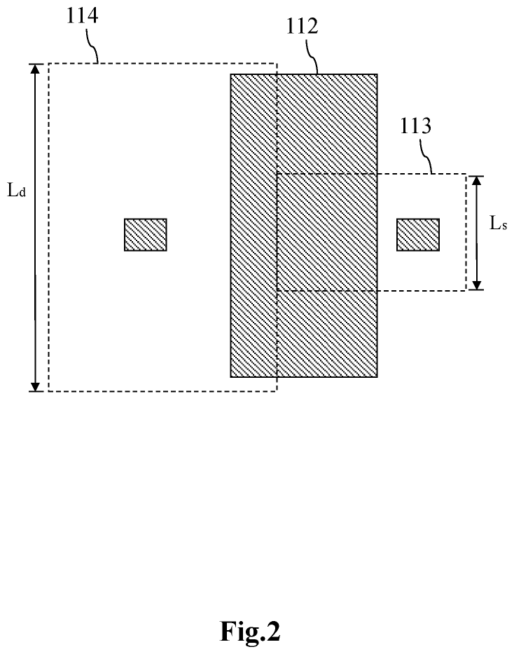

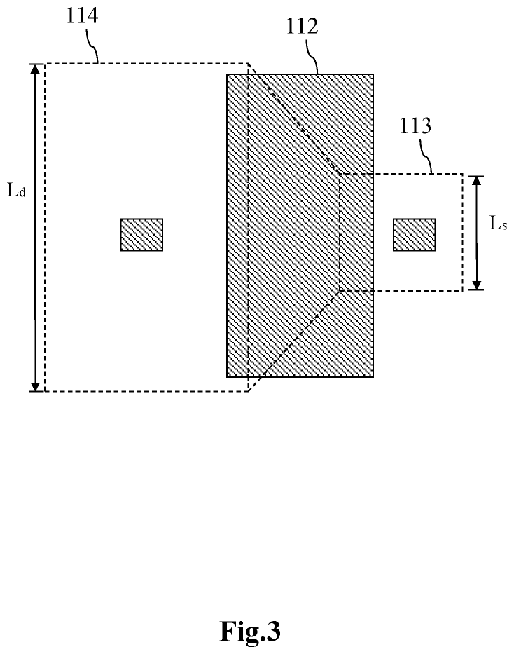

In the invention, the widths of the source 113 and the drain 114 are the side lengths along a horizontal axis direction (i.e. the direction parallel to the direction from the source 113 to the drain 114), as shown in FIG. 1. It is shown that the width W_{d} of the drain 114 is larger than the width Wₛ of the source 113 in the embodiment. Moreover, the lengths of the source 113 and the drain 114 may also be different. As shown in FIG. 2, the length L_{d} of the ion doping region of the drain 114 is larger than the length Lₛ of the ion doping region of the source 113 in the embodiment. In addition, as shown in FIG. 3, the length L_{d} of the ion doping region of the drain 114 is larger than the length Lₛ of the ion doping region of the source 113 in another embodiment, and a tilt angle is presented between the opposite sides of the ion doping regions of the drain 114 and the source 113.

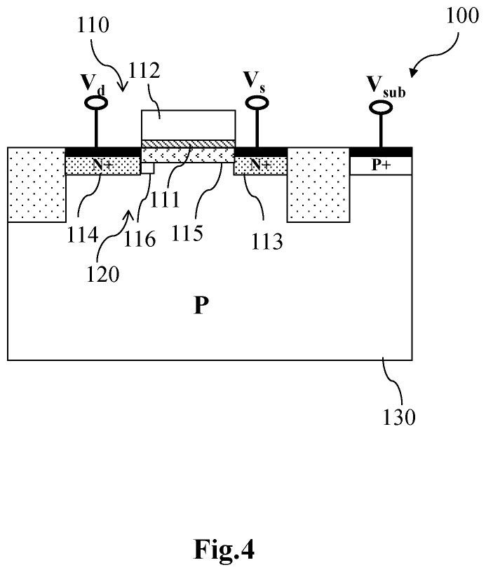

The single-gate multiple-time programming non-volatile memory 100 is a three-terminal structure. As shown in FIG. 4, the three terminals are respectively a source, a drain and a substrate. A substrate voltage V_{sub}, a source voltage Vₛ and a drain voltage V_{d} are respectively applied to the P-type semiconductor substrate 130, the source 113 and the drain 114. The single-gate multiple-time programming non-volatile memory 100 operates as follows:

In writing,
a. V_{sub}=ground (0);
b. V_{d}=Vₛ=HV (High Voltage);
   V_{d}=HV (High Voltage), and Vₛ=MV (Medium Voltage) or LV (Low Voltage); or
   V_{d}=MV (Medium Voltage), and Vₛ=LV (Low Voltage) or ground (0).

In erasing,
a. V_{sub}=ground (0);
b. V_{d}=HV (High Voltage), and Vₛ=ground (0);
   V_{d}=HV (High Voltage), and Vₛ=floating voltage;
   Vₛ=HV (High Voltage), and V_{d}=ground (0); or
   Vₛ=HV (High Voltage), and V_{d}=floating voltage.

Furthermore, the ranges of “High Voltage”, “Medium Voltage” and “Low Voltage” proposed in the above bias conditions are specifically described. The “High Voltage” refers to subtract the threshold voltage Vₜ of the transistor from the breakdown voltage of the drain to the source. The “Medium Voltage” refers to half of the breakdown voltage of the drain to the source. The “Low Voltage” refers to one quarter of the breakdown voltage of the drain to the source.

The structure of FIG. 1 is disposed in a P-type silicon wafer. The isolation structure is disposed with a standard isolation module process. After the basic isolation structure is completed, the channel of the NMOS transistor is disposed with an ion implant process. After the dielectric layers of the first conduction gate is grown, polysilicon is deposited. Next, a photolithographic process is used to pattern the polysilicon to form the single floating gate. Next, another ion implant process is undertaken to form the electrodes of the NMOS transistor—the drain and source. After metallization, the fabrication of a great number of the single-gate multiple-time programming non-volatile memory is completed.

In conclusion, compared with a conventional single-gate programming non-volatile memory having high cost due to complicated control, the single-gate multiple-time programming non-volatile memory and the operation method thereof of the present invention can greatly reduce the lengths of control lines, areas and production cost of the non-volatile memory on account of simple operation and the least elements and the least control voltages.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A single-gate multiple-time programming non-volatile memory comprising:
a P-type semiconductor substrate;
a transistor comprising a first dielectric layer, a first conduction gate and a plurality of ion-doped regions, said first dielectric layer is disposed on said P-type semiconductor substrate, and said first conduction gate is stacked on said first dielectric layer, and said ion-doped regions are respectively disposed at two sides of said first conduction gate to function as a source and a drain and disposed in said P-type semiconductor substrate, wherein the source and the drain have different widths; and
a capacitor structure disposed on said P-type semiconductor substrate, and the edge of the drain is utilized to serve as a capacitor to control a floating gate and comprises a lightly-doped region between the drain and the floating gate, and said lightly-doped region and said ion-doped regions are doped with the same type of ions, and forming a single floating gate.

2. An operation method of a single-gate multiple-time programming non-volatile memory, and said non-volatile memory comprises a P-type semiconductor substrate, a transistor and a capacitor structure, and said transistor and said capacitor structure are disposed in said P-type semiconductor substrate, and said transistor comprises a first dielectric layer, a first conduction gate and a plurality of ion-doped regions, said first dielectric layer is disposed on said P-type semiconductor substrate, and said first conduction gate is stacked on said first dielectric layer, and said ion-doped regions are respectively disposed at two sides of said first conduction gate to function as a source and a drain and disposed in said P-type semiconductor substrate, wherein the source and the drain have different widths, and the edge of the drain is utilized to serve as a capacitor to control a floating gate and comprises a lightly-doped region between the drain and the floating gate, and said lightly-doped region and said ion-doped regions are doped with the same type of ions, and forming a single floating gate, and said operation method is characterized in:
respectively applying a substrate voltage V_{sub}, a source voltage Vₛ and a drain voltage V_{d} to said P-type semiconductor substrate, said source and said drain;
in writing said non-volatile memory,
a. V_{sub}=ground (0);
b. V_{d}=Vₛ=HV (High Voltage);
V_{d}=HV (High Voltage), and Vₛ=MV (Medium Voltage) or LV (Low Voltage); or
V_{d}=MV (Medium Voltage), and Vₛ=LV (Low Voltage) or ground (0); and
in erasing said non-volatile memory,
a. V_{sub}=ground (0);
b. V_{d}=HV (High Voltage), and Vₛ=ground (0);
V_{d}=HV (High Voltage), and Vₛ=floating voltage;
Vₛ=HV (High Voltage), and V_{d}=ground (0); or
Vₛ=HV (High Voltage), and V_{d}=floating voltage.
